(19) United States
(12) Patent Application Publication
(10) Pub. No.: US 2020/0232724 A1
(43) Pub. Date: Jul. 23, 2020

(54) Modularized Water-Cooling Heat Sink

(71) Applicant: Dongguan Jianxin Electronic Technology Co., Ltd., Dongguan (CN)

(72) Inventor: Jianqiang Deng, Dongguan (CN)

(73) Assignee: Dongguan Jianxin Electronic Technology Co., Ltd.

(21) Appl. No.: 16/374,439

(22) Filed: Apr. 3, 2019

(30) Foreign Application Priority Data
Jan. 23, 2019 (CN) 201910063610.9
Jan. 23, 2019 (CN) 201920125084.X

(51) Int. Cl. F28F 9/26; H05K 7/20

(52) U.S. Cl. CPC F28F 9/262; F28F 2250/08; H05K 7/20272; H05K 7/20263

(57) ABSTRACT

A modularized water-cooling heat sink includes a cold discharge body, a water tank and a water pump. The water pump is connected with the water tank, and connected with the cold discharge body via an external cold head. The cold discharge body is provided with a first through hole in communication with outside, and the water pump is provided with a second through hole in communication with outside. The first through hole is located on the end of the cold discharge body away from the connection with the water pump. The water tank and the cold discharge body are detachably connected. The modularized water-cooling heat sink has such a modular structure design that it is assembled as simple as an integrated water-cooling heat sink, and that the heat dissipation effect thereof is as good as a split water-cooling heat sink.

### FIELD OF THE INVENTION

The invention relates to heat sinks and, in particular, to a modularized water-cooled heat sink.

### BACKGROUND OF THE INVENTION

In the do-it-yourself (DIY) realm of computer peripherals, water cooling has always been the preferred scheme for advanced enthusiasts to build computers. Compared with air cooling, water cooling has a better cooling effect for CPU overclocking. Nevertheless, the space required for water cooling is larger. The schemes of traditional water-cooling heat sinks are divided into integrated and split water cooling. The integrated water cooling scheme generally involves a cold head, a cold discharge, and a fan disposed on the cold discharge. Since the integrated water-cooling heat sinks can be installed in computers right out of the box, they are widely accepted by DIY users. However, its heat dissipation effect is not as good as split water cooling. The split water cooling scheme, on the other hand, has a larger heat capacity and a slower temperature rise, thus featuring a better cooling effect than the integrated water cooling. Unfortunately, it has a complicated installation procedure and costs more, hindering its popularity on the market. It is therefore desirable to have a water-cooling heat sink that can be installed as easily as the integrated water-cooling ones and have a heat dissipation effect as good as the split water-cooling ones.

In addition, the internal structure of the conventional cold discharge has equal left and right parts. The water flow rate is small, and the heat dissipation efficiency is low.

### SUMMARY OF THE INVENTION

To overcome the shortcomings and deficiencies in the prior art, an objective of the invention is to provide a modularized water-cooling heat sink, which has a modularized structure for easy installation as integrated water-cooling ones and a heat dissipation effect as good as split water-cooling ones.

The disclosed modularized water-cooling heat sink includes a cold discharge body, a water tank and a water pump, wherein the water pump is in fluid communication with the water tank, and in fluid communication with the cold discharge body via an external cold head; the cold discharge body is provided with a first through hole in communication with outside, the water pump is provided with a second through hole in communication with outside; the first through hole is located at one end of the cold discharge body away from the connection with the water pump; and the water tank and the cold discharge body are connected in a detachable way.

The water pump is provided on one end of the water tank, and both the water tank and the water pump are disposed on the side of the cold discharge body near the first through hole.

The water pump is provided on one end of the water tank, and both the water tank and the water pump are disposed on the side of the cold discharge body away from the first through hole.

The water tank and the water pump are integrally formed.

The first through hole is connected with a first pipe, and the second through hole is connected with a second pipe.

The cross sections of the water pump and the water tank are both rectangular.

The areas of the cross sections of the water pump and the water tank are the same.

The thickness of the cold discharge body is not larger than the thickness of the water tank.

The cold discharge body includes a frame and a plurality of ducts therein. The first through hole is formed on one end of the frame. One end of the frame is in fluid communication with the other end thereof via the ducts.

The invention has the following advantages:

Simple installation: The disclosed modularized water-cooling heat sink can be installed in a case together with the water tank and the cold discharge through the detachable connection of the water tank and the cold discharge, thereby greatly reducing the difficulty in installing the heat sink. According to the needs of the DIY user, the water tank and the cold discharge can be installed separately in the case.

Good heat dissipation effect: Since the internal structure of the traditional cold discharge has equal left and right parts, the water flow rate is small and the heat dissipation efficiency is low. The modularized water-cooling heat sink of the invention allows the coolant inside the cold discharge body to flow from one end to the other end thereof, owing to the fact that the first through hole and the connection between the water pump and the cold discharge are located on opposite ends of the cold discharge body. During the flowing process, the coolant can fully exchange heat with the cold discharge body, thereby improving the heat dissipation effect.

### BRIEF DESCRIPTION OF THE DRAWINGS

FIG. 1 is a schematic three-dimensional view of the invention; and

FIG. 2 is an exploded view of the invention.

### DESCRIPTION OF THE PREFERRED EMBODIMENTS

The aforementioned and other objectives and advantages of this disclosure will become clearer in light of the following detailed description of an illustrative embodiment of this invention described in connection with the drawings.

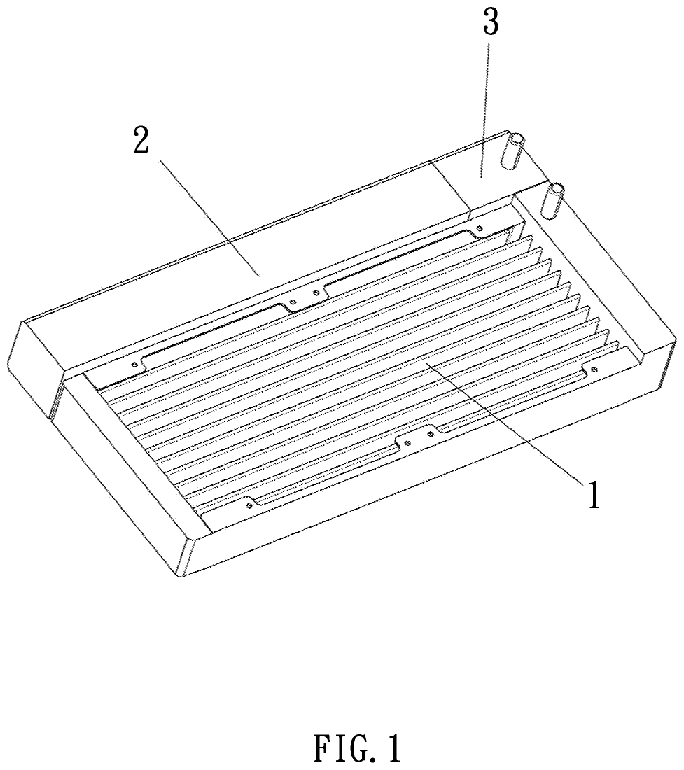

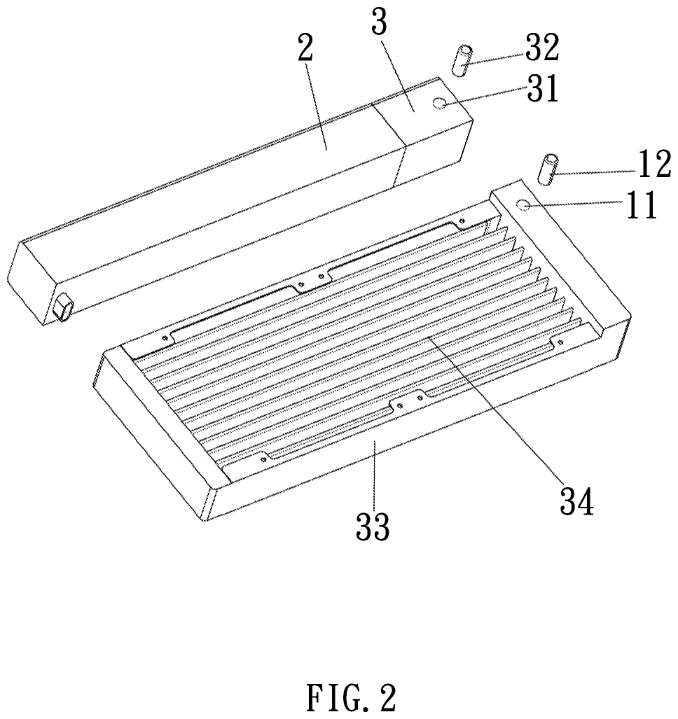

With reference to FIGS. 1 and 2, the disclosed modularized water-cooling heat sink includes a cold discharge body 1, a water tank 2, and a water pump 3. The water pump 3 is in fluid communication with the water tank 2, and is in fluid communication with the cold discharge body 1 via an external cold head. The cold discharge body 1 is provided with a first through hole 11 in communication with the outside. The water pump 3 is provided with a second through hole 31 in communication with the outside. The first through hole 11 is located at one end of the cold discharge body 1 away from the connection with the water pump 3. The water tank 2 and the cold discharge body 1 are connected in a detachable way.

More explicitly, the cold discharge body 1 includes a frame 33 and a plurality of ducts 34 therein. The first through hole 11 is formed on one end of the frame 33. One end of the frame 33 is in fluid communication with the other end thereof via the ducts 34.

The disclosed modularized water-cooling heat sink achieves the following advantages:

Simple installation: The disclosed modularized water-cooling heat sink can be installed in a case together with the water tank 2 and the cold discharge through the detachable connection of the water tank 2 and the cold discharge, thereby greatly reducing the difficulty in installing the heat sink. According to the needs of the DIY user, the water tank 2 and the cold discharge can be installed separately in the case.

Good heat dissipation effect: Since the internal structure of the traditional cold discharge has equal left and right parts, the water flow rate is small and the heat dissipation efficiency is low. The modularized water-cooling heat sink of the invention allows the coolant inside the cold discharge body to flow from one end to the other end thereof, owing to the fact that the first through hole 11 and the connection between the water pump 3 and the cold discharge body 1 are located on opposite ends of the cold discharge body 1. During the flowing process, the coolant can fully exchange heat with the cold discharge body 1 via the ducts 34, thereby improving the heat dissipation effect.

In the present embodiment, similar to the traditional split water-cooling heat sinks, the water tank 2 and the water pump 3 are integrally formed or two separate components that are integrated by assembly. Specifically, the water pump 3 is provided on one end of the water tank 2. According to needs, the DIY user can install both the water tank 2 and the water pump 3 on one side of the cold discharge body 1, or install both the water tank 2 and the water pump 3 on the other end of the cold discharge body 1, as long as the positions thereof do not affect the heat dissipation effect of the cold discharge body 1.

In an embodiment of the modularized water-cooling heat sink, the first through hole 11 is connected with a first pipe 12 and the second through hole 31 is connected with a second pipe 32, facilitating the connection and fluid communication between the cold discharge body 1 and the cold head via a soft pipe.

For a better appearance, the heat sink in the present embodiment has a rectangular cross section for both the water pump 3 and the water tank 2 with the areas thereof being the same. In addition to a rectangular cross section, the water pump 3 and the water tank 2 can also have different shapes from the present embodiment, and can adopt a design with different cross-sectional areas. The cross sections of the water pump 3 and the water tank 2 described in this embodiment are both optimized choices. It should be construed that other shapes and areas of the cross sections of the water pump 3 and the water tank 2 are still within the scope of this invention.

In this embodiment, the thickness of the cold discharge body 1 is not greater than the thickness of the water tank for the ease of installing the heat sink.

While the invention is described in some detail hereinbelow with reference to certain illustrated embodiments, it is to be understood that there is no intent to limit it to those embodiments. On the contrary, the aim is to cover all modifications, alternatives and equivalents falling within the spirit and scope of the invention as defined by the appended claims.

What is claimed is:

1. A modularized water-cooling heat sink, comprising a cold discharge body 1, a water tank (2), and a water pump (3), wherein one end of the water tank (2) is in fluid communication with the water pump (3) and the other end thereof is in fluid communication with the cold discharge body (1); the water pump (3) is in fluid communication with the cold discharge body (1) via an external cold head; the cold discharge body (1) is provided with a first through hole (11) in fluid communication with outside and the water pump is provided with a second through hole (31) in fluid communication with the outside; the first through hole (11) is located on the end of the cold discharge body (1) away from the connection thereof with the water pump (3); and the water tank (2) and the cold discharge body (1) are connected in a detachable way.

2. The modularized water-cooling heat sink of claim 1, wherein the water pump (3) is disposed on one end of the water tank (2), and the water tank (2) and the water pump (3) are both disposed on the side of the cold discharge body (1) near the first through hole (11).

3. The modularized water-cooling heat sink of claim 1, wherein the water pump (3) is disposed on one end of the water tank (2), and the water tank (2) and the water pump (3) are both disposed on the side of the cold discharge body 1 away from the first through hole (11).

4. The modularized water-cooling heat sink of claim 1, wherein the water tank (2) and the water pump (3) are integrally formed.

5. The modularized water-cooling heat sink of claim 1, wherein the first through hole (11) is connected with a first pipe (12) and the second through hole (31) is connected with a second pipe (32).

6. The modularized water-cooling heat sink of claim 1, wherein the cross section of the water pump (3) and the cross section of the water tank (2) are both rectangular.

7. The modularized water-cooling heat sink of claim 1, wherein the areas of the cross sections of the water pump (3) and the water tank (2) are the same.

8. The modularized water-cooling heat sink of claim 1, wherein the thickness of the cold discharge body (1) is not greater than the thickness of the water tank (2).

9. The modularized water-cooling heat sink of claim 1 with the cold discharge body (1) including a frame (33) and a plurality of ducts (34) therein, wherein the first through hole (11) is formed on one end of the frame (33), and one end of the frame (33) is in fluid communication with the other end thereof via the ducts (34).
